(19) United States
(12) Patent Application Publication
(10) Pub. No.: US 2026/0305460 A1
(43) Pub. Date: Oct. 1, 2026

(54) COMPONENT PACKAGE AND METHOD FOR THE PRODUCTION THEREOF

(71) Applicant: ams-OSRAM International GmbH, Regensburg (DE)

(72) Inventors: Andreas FROEHLICH, Regensburg (DE); Joerg Erich SORG, Regensburg (DE); Tobias HAUPELTSHOFER, Breitenbrunn (DE); Erik HEINEMANN, Regensburg (DE)

(73) Assignee: ams-OSRAM International GmbH, Regensburg (DE)

(21) Appl. No.: 19/484,169

(22) PCT Filed: May 15, 2024
(86) PCT No.: PCT/EP2024/063381

§ 371 Date: Nov. 13, 2025

(30) Foreign Application Priority Data
May 15, 2023 (DE) 10 2023 112 753.5

(51) Int. Cl. H10W 76/18; H10W 20/20

(52) U.S. Cl. CPC H10W 76/18; H10W 20/211

(57) ABSTRACT

The invention relates to a component package, including a chip with a first main side and an opposing second main side, wherein a first number of contact areas are formed on the first main side for connecting an optoelectronic component, in particular a laser assembly, and a second number of contact areas are formed on the second main side for connecting to a carrier, in particular a PCB. The semiconductor chip includes at least one layer with an integrated circuit, which is coupled at least to portions of the first number and at least to portions of the second number of contact areas for its power supply. An optoelectronic component is connected to at least two of the first number of contact areas. A glass cap is also provided, which is arranged over the optoelectronic component forming a chamber, and is connected substantially inorganically, in particular hermetically, to the first main side.

### CROSS-REFERENCE TO RELATED APPLICATIONS

This application is a national stage entry from International Application No. PCT/EP2024/063381, filed on May 15, 2024, published as International Publication No. WO 2024/236039 A2 on Nov. 21, 2024, and claims the priority of German patent application DE 10 2023 112 753.5 dated May 15, 2023, the disclosures of all of which are hereby incorporated by reference in their entireties.

### FIELD

The present invention relates to a component package and a method for processing the same.

### BACKGROUND

Semiconductor lasers, in particular vertical laser diodes known as VCSELS, but also edge-emitting lasers, are increasingly being used for a variety of display applications, as well as in other areas. They are characterized by relatively high light output and fast switching times. In order to ensure this light output on a permanent basis, such semiconductor lasers are often hermetically sealed to prevent contamination, oxidation, or carbon deposits on the laser's output facet. Such hermetically sealed laser packages usually require a ceramic substrate, which is then sealed with a suitable cover, for example a glass cover. The closure forms a hermetic seal, preventing gas exchange with the environment and, in particular, the ingress of organic substances that would otherwise lead to deposits on the laser's exit surface.

There are now several options for connecting to a suitable control system. On the one hand, a driver module can either be inserted directly into the cavity of the laser package or placed outside on the carrier, e. g., a PCB. Due to the high requirements of the laser or laser package on the carrier in terms of high thermal conductivity to dissipate the heat generated during operation, a very good flat base for connecting the cover, and a small cavity to reduce the amount of gas inside the hermetic package, integrating the driver in-side the cavity proves to be difficult. In addition, it has been found that signal routing on the surface of the substrate can lead to potential difficulties with hermetic sealing.

Alternatively, the driver and/or control chip can be placed outside the hermetic package directly on the carrier, e.g., a PCB. Although this has the advantage of greater flexibility, for example in the selection of available drivers, such a component, which implements control and driver circuits, for example, usually has a large lateral extension, i.e., a large footprint, which increases the overall dimensions of the combined laser package and control arrangement.

There is therefore a need for hermetically sealed laser packages, in particular in the form of component packages, in which lateral space consumption is minimized as far as possible so that a high integration density on a substrate carrier is possible.

### SUMMARY THE INVENTION

This need is met by the subject matter of the independent patent claims. Further developments and embodiments of the proposed principle are specified in the dependent claims.

The inventors propose to dispense with the implementation of a complex and expensive ceramic substrate and instead to use the semiconductor surface of a drive and/or control circuit for the laser package directly as a substrate for implementing the hermetic laser package.

The inventors take advantage of the fact that a control circuit has a large surface area that is suitable for implementing contact connection options for mounting an optoelectronic component, optionally also with a submount. An optoelectronic component, e. g., a laser, can be arranged on the surface of the control circuit in a space-saving manner, either using a flip-chip process or two bond pads. A glass cap is suitable for creating a hermetic seal, which is firmly and, in particular, hermetically connected to the surface of the semiconductor chip by means of various other measures.

This allows the available space to be optimized, thereby achieving a very high integration density of semiconductor chips, comprising, for example, control or driver circuits and the associated optoelectronic components or laser packages. In addition, additional contacts for mounting further passive or active components such as capacitors, resistors, or coils, or even further chips, can be formed on the remaining space on the upper side of the half-chip. This can advantageously be done outside the hermetically sealed area, so that the hermetically sealed space is minimized and remains limited to the laser package.

In one aspect, the component package thus comprises, in particular, a semiconductor chip with a first main side and an opposite second main side. A first number of contact areas are arranged on the first main side, which are designed and provided for connecting an optoelectronic component, in particular a laser arrangement.

A second number of contact areas is provided on the second main side, which in turn are designed for connection to a carrier, in particular a PCB board. According to the proposed principle, the semiconductor chip has at least one layer with an integrated circuit that is coupled to at least parts of the first number and at least parts of the second number of contact areas for its power supply.

In this context, the semiconductor chip may comprise one or more integrated circuits, each of which performs different functions and is located in different areas of the semiconductor chip. In addition to supply circuits such as controllable power sources and others, these include modulation circuits or digital components for converting digital control signals. In this context, the semiconductor chip can, for example, be designed using a suitable technology (including, but not limited to, silicon-based CMOS technology). The integrated circuits in this context can include digital circuits as well as analog circuits such as driver circuits or supply circuits for the optoelectronic component. The technology is optimised for the respective function to be performed.

The component package according to the proposed principle also comprises an optoelectronic component, in particular a laser arrangement such as an edge-emitting laser or a VCSEL, which is connected to at least two of the first number of contact surfaces. Finally, a glass cap is arranged above the optoelectronic component, forming a space and thus enclosing at least two of the first number of contact surfaces. The glass cap is essentially inorganic and connected to the first main side, whereby this connection also constitutes a hermetic seal.

In the proposed principle, the semiconductor chip or its surface is thus used as a substrate for the arrangement of the optoelectronic component. Since the surface of the semiconductor chip consists in particular of silicon or another semiconductor material, oxygen diffusion or other gas diffusion through this layer is largely prevented. This allows a glass cap to be provided that bonds hermetically with the surface material, ensuring a gas-tight seal of a space within the glass cap.

The proposed component package thus provides both the necessary driver circuits and a hermetically sealed laser package in a very confined space.

In one aspect, the connection between the glass cap and the first main side can be essentially carbon-free. In other words, the connection is not only inorganic but also free of carbon, which prevents any degradation of the connection even at very high laser intensities or shorter wavelengths and keeps the laser facet free of carbon deposits.

In one aspect, a connection surface, in particular a metallic one, can be provided on the upper side, i.e., the first main side of the semiconductor chip. This surrounds at least partially the at least two contact surfaces on which the optoelectronic component is mounted. The connection surface on the first main side is designed to be connected to the underside of an edge of the glass cap in a material-locking manner. In one embodiment, the connection surface may comprise a material that differs from the base material of the semiconductor chip. For example, the connection surfaces may be metallic and thus be designed similarly and in the same way as the contact surfaces. Alternatively, it is also possible to provide a specially designated area on the upper side made of a semiconductor material, in particular the same semiconductor material as the semiconductor chip.

A material bond between the edge of the glass cap and the contact pads can be achieved in various ways. In one aspect, an underside of the edge of the glass cap can be bonded to the contact pads by means of glass bonding or a similar bonding process. In an alternative aspect, the underside of an edge of the glass cap can also be welded to the connection surface on the semiconductor chip, for example by welding the underside of the edge of the glass cap or by welding the material of the connection surfaces. In a further alternative design, the edge of the glass cap can also be soldered to the connection surface.

In a further aspect, the second number of contact areas is formed by a so-called ball grid array. This has the advantage that it can be implemented with a high integration density on the underside of the semiconductor chip, so that its lateral space consumption is minimized when placing the semiconductor chip on a carrier, e.g., a PCB. Optionally, at least some of this second set of contact surfaces can be electrically connected to contact surfaces of the first set of contact surfaces by a conductor ( ). For example, this makes it possible for supply lines for the optoelectronic component to be routed through the semiconductor chip directly from the second set of contact surfaces to the first set of contact surfaces.

Another aspect deals with the distribution of the individual lines to the contact pads of the first and second sets. For this purpose, the semiconductor chip may have at least one rewiring layer connected to at least some of the first set of contact pads and the second set of contact pads. This allows the first and second sets of contact pads to be restructured so that they are routed to the integrated circuits in the semiconductor chip, which are located in different places for design reasons, or to the second set of contact pads. Such a rewire layer can be formed both below and above the layer with the integrated circuits.

In some aspects, the rewiring layer is formed between the first main side and the layer with the integrated circuit and also has the functionality of a thermal dissipation for the heat generated by the optoelectronic component. Such heat dissipation is effected on the one hand by the material of the rewire layer itself, but also by the highly conductive and, in particular, metallic conductors located therein.

In some aspects, the rewiring layer comprises several through-plugs. These can be routed through the rewiring layer but also through other areas of the semiconductor chip and connect at least some of the first number of contact areas to at least some of the second number of contact areas. In this context, it can be noted that design considerations relating to the integrated circuits within the semiconductor chip necessitate a specific positioning of these within the layers of the semiconductor chip. As a result, the through-plating cannot be carried out at any location. Rather, in some aspects, it is intended that the through—s are located essentially along a circumferential edge, i.e., in the outer region of the semiconductor chip.

The semiconductor chip can be constructed from various base materials. Silicon is worth mentioning here, as the available technology is well known and integrated circuits can be manufactured in silicon in various ways using different technologies. However, other materials such as GaN or GaAs materials are also known for fast circuits.

In one aspect, the semiconductor chip comprises a substrate layer made of a semiconductor material and, in particular, one of the aforementioned materials, which is free of the integrated circuit. This additional substrate layer can already be provided during the manufacturing process of the semiconductor chip, but can also be applied to the layer with the integrated circuits afterwards using various manufacturing and connection techniques. It is also conceivable that the circuits are not only provided in a single layer within the semiconductor chip, but also in several stacked structures. These can in turn be separated from each other by internal rewiring layers. The substrate layer is arranged in some respects between the layer with the integrated circuits and the first main side and can serve, for example, as a heat reservoir or for heat dissipation from the optoelectronic component. In some aspects, the surface of the substrate layer may also form the first main side. In this context, it is also possible to form a redistribution layer and a substrate layer in a common structure.

In some aspects, the first number of contact areas comprises a larger number than would be necessary for controlling and supplying the optoelectronic component. In particular, further contact areas of the first number may be provided which are designed for connection to passive or active SMD components. Accordingly, the first main side of the semiconductor body can be provided with additional contact areas, onto which SMD components can in turn be placed in a further assembly step and soldered to this. Such assembly can be carried out before or after the assembly of semiconductor chips on a carrier, in particular a PCB board. It is also possible to install the components before or after placing the optoelectronic component.

Possible passive components in this context include resistors, capacitors, or coils. Possible sizes for such components include, for example, 0402, 0603, or 0201 sizes, but depending on the size of the existing semiconductor chip, other SMD components in various sizes may also be arranged.

In a further and also alternative design, a large number of the first set of contact surfaces are formed for connection to a second semiconductor chip. The second semiconductor chip is placed on the first main side of the first semiconductor chip and connected to it. The second semiconductor chip contains an integrated circuit. In a simple case, the integrated circuit is formed by an active component, for example a transistor. Accordingly, both passive and active components and even integrated circuits with more complex functions can be applied to the first main side. In some aspects, the contact areas provided for this purpose on the first main side can also be provided with contact areas of the second number in order to be able to provide the necessary power supply for the second semiconductor chip or the passive or active components.

The existing stacking of several semiconductor chips on top of each other allows semiconductor chips with different functions for the control and monitoring of an optoelectronic component to be stacked in a space-saving manner. At the same time, the design with different semiconductor chips allows optimization for the respective technology. For example, special driver circuits with high current and power consumption can be combined in a space-saving manner with digital circuits in a second chip for controlling the optoelectronic component.

In a further aspect, the first number of contact surfaces are at least partially integrated into the first main side. Alternatively, the first number of contact surfaces or parts thereof may at least partially protrude beyond a surface of the first main side. By combining the different types and designs of the first number of contact surfaces, it is possible to combine different mounting options.

Another aspect concerns the generation of heat and its dissipation during operation of the component package according to the invention. In some aspects, it may be provided that the integrated circuits in the position of the semiconductor chip are arranged laterally spatially separated from the at least two contact surfaces provided for contacting the optoelectronic component. By means of a suitable design of the integrated circuits and their arrangement within the semiconductor chip, it is possible to define areas in which heat dissipation, in particular heat generated by the optoelectronic component, is ensured by a heat dissipation path in the semiconductor chip without this interacting negatively with the integrated circuits.

For example, it is possible in one aspect that integrated circuits or sub-areas thereof, which operate with a high power dissipation during operation, are arranged outside a heat dissipation path of the optoelectronic component. In other words, a first integrated circuit with a higher heat dissipation during operation is arranged at a greater lateral distance from at least two of the first number of contact surfaces than a second integrated circuit with a lower heat dissipation. Heat dissipation paths for the optoelectronic component can be defined by further suitable structural measures, such as the formation of more highly doped insulated semiconductor layers.

Their channels ensure improved heat dissipation through the semiconductor chip, so that laser packages with higher loss effects can be integrated on the semiconductor chip in a space-saving manner.

Another aspect concerns a method for processing a component package and, in particular, a laser package according to the proposed principle shown above.

In this method, a semiconductor chip is provided in a first step, which has a first main side and an opposite second main side. A number of contact surfaces are formed on the first main side, some of which are intended for connecting an optoelectronic component and, in particular, a laser arrangement. The optoelectronic component can be placed directly on the contact areas or on a submount. Alternatively, they can also be placed in such a way that a connection to the component is created by bond wires.

On the second main side, there is a second number of contact areas for connection to a carrier and, in particular, a PCB. In the proposed principle, the semiconductor chip comprises at least one layer with an integrated circuit, which in turn is coupled at least to parts of the first number and at least also to parts of the second number of contact areas for its power supply and for controlling the optoelectronic component.

In a further step, an optoelectronic component is now applied to at least two of the first number of contact surfaces and connected to it electrically and mechanically. Alternatively, the optoelectronic component can also be placed next to it, mechanically secured, and then electrically contacted by means of bonding wires. A glass cap is then placed on the first main side, forming a space above the optoelectronic component and the two contact surfaces. This space can be designed so that it encloses the optoelectronic component as closely as possible, i.e., without any further larger space. The glass cap is then bonded to the first main side of the semiconductor chip in a material-locking and, in particular, hermetic manner using a predominantly inorganic process. This bond is formed along a circumferential edge of the glass cap with the first main side of the semiconductor chip.

The proposed method creates a component package in which possible impedances and other parasitic effects are reduced by directly connecting the semiconductor chip to the optoelectronic component. The associated switching times can thus be further reduced and adapted to the respective application.

Another aspect concerns the material-locked and, in particular, hermetic connection between the glass cap and the semiconductor chip. For this purpose, for example, an underside of the edge of the glass cap can be formed with a connection surface, in particular a metallic one. The connection surface on the surface of the semiconductor chip is already formed during the manufacture of the semiconductor chip using suitable and designated technologies. The metallic connection surface is suitable in that it is bonded to an underside of the edge of the glass cap, in particular by means of a glass bonding process.

Alternatively, an underside of an edge of the glass cap can also be welded to the connection surface on the first main side, in particular by partially welding a surface of the underside. In this context, it is also possible to weld the metallic connection surface and hermetically bond it to the glass cap, provided that this process does not cause excessive thermal stress on the integrated circuit located in the semiconductor chip. The bonding or welding processes can be carried out using laser radiation, in particular through the glass cap. In a further alternative aspect, an underside of an edge of the glass cap can also be soldered to the connection surface.

The space-saving component package produced in this way can be improved in further aspects so that a particularly space-saving staggering of different assemblies is achieved and the space required for the component package on the PCB is minimized. For this purpose, in some aspects, one or more passive SMD components can be applied to two of the first number of contact surfaces, in particular outside the glass cap, and connected to it., active SMD components can also be applied to the first number of contact surfaces, i.e., on the first main side outside the glass cap, and connected to it.

In a further aspect, it is also possible to apply additional semiconductor chips with one or more integrated circuits to parts of the first number of contact surfaces outside the glass cap and to connect them to these. These aspects can be implemented before or after the optoelectronic component is applied and, in particular, before or after the glass cap is applied.

Accordingly, it is possible to completely manufacture the component package except for the optoelectronic assembly and the optional hermetic seal and then apply the optoelectronic component. This also allows a functional test of the entire component package to be carried out easily with the laser. It is also possible, after complete assembly with SMD components or stacking with additional semiconductor chips, to align and test the applied optoelectronic component and then attach the glass cap. This allows for sufficient testing depth even during the manufacturing phase, thereby maximizing the yield in the production of the component package and further reducing costs.

In this regard, the glass cap and the semiconductor chip can be manufactured in a wafer assembly. Accordingly, a glass wafer is provided with a plurality of such glass caps, whose geometric alignment with each other corresponds to a corresponding alignment of a structured surface of a semiconductor wafer. This contains a plurality of integrated circuits and several first contact areas. After the optoelectronic components have been assembled and the caps have been placed and sealed, the finished component packages can be separated.

In a further aspect, a geometric arrangement of at least two of the first number of contact surfaces on the first main side of the semiconductor chip can be designed such that, with regard to integrated circuits within the semiconductor body with a high heat dissipation capacity, they are located at a particularly large spatial lateral distance. This lateral distance enables improved cooling of the optoelectronic component and the integrated circuits with higher power dissipation, for example by forming several different heat dissipation paths through the semiconductor chip.

### BRIEF DESCRIPTION OF THE DRAWINGS

Further aspects and embodiments according to the proposed principle will become apparent in relation to the various embodiments and examples described in detail in connection with the accompanying drawings.

FIG. 1 shows a first embodiment of a component package with some aspects according to the proposed principle;

FIG. 2 shows a second embodiment of a component package with some aspects according to the proposed principle;

FIG. 3 shows a third t embodiment of a component package with some aspects according to the proposed principle;

FIG. 4 shows a fourth embodiment of a component package in plan view to illustrate some aspects according to the proposed principle;

FIG. 5 is a top view of a design of a component package with some aspects according to the proposed principle;

FIG. 6 shows an intermediate result of a method for manufacturing a wafer composite with a plurality of such component packages;

FIG. 7 is a representation of a method for manufacturing a component package.

### DETAILED DESCRIPTION

The following embodiments and examples show various aspects and combinations thereof according to the proposed principle. The embodiments and examples are not always to scale. Likewise, various elements may be enlarged or reduced in size to highlight individual aspects. It goes without saying that the individual aspects and features of the embodiments and examples shown in the figures can be readily combined with each other without compromising the principle of the invention. Some aspects have a regular structure or shape. It should be noted that in practice, slight deviations from the ideal shape may occur without contradicting the inventive idea.

Furthermore, the individual figures, features, and aspects are not necessarily shown in their correct size, and the proportions between the individual elements do not necessarily have to be correct. Some aspects and features are emphasized by being shown enlarged. However, terms such as “above,” “above,” “below,” “below,” “larger,” “smaller,” and the like are correctly represented in relation to the elements in the figures. It is thus possible to deduce such relationships between the elements from the illustrations.

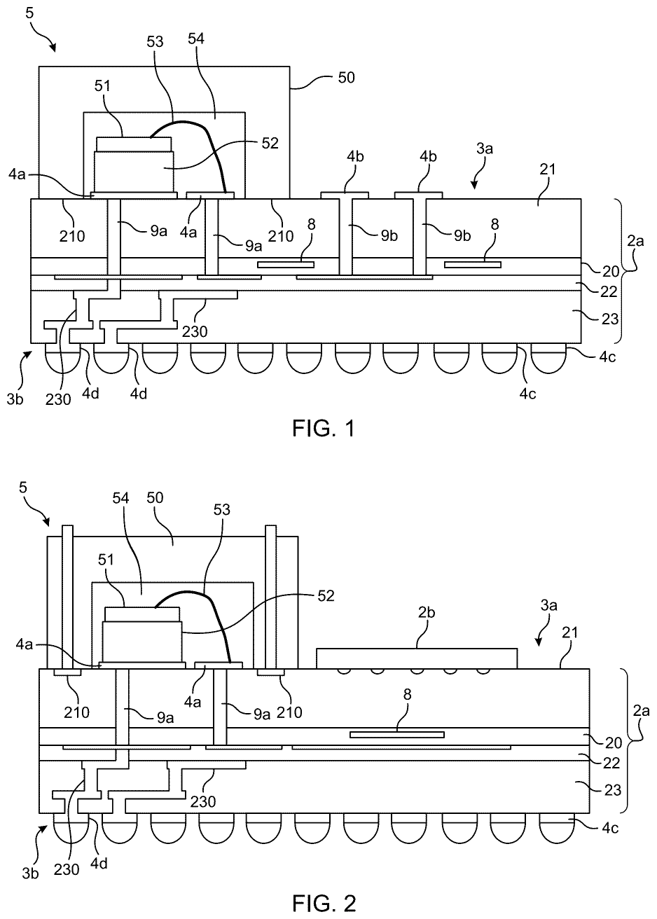

FIG. 1 shows a component package according to the proposed principle. The design is shown here as an isolated component package prior to mounting on a PCB or other substrate, and comprises a semiconductor chip 2a with a hermetically sealed laser assembly 5 on it. The semiconductor chip is made of silicon and contains a plurality of stacked layers, each of which has a different functionality and therefore also a different design. These layers can be produced integrally on a wafer, i.e., as a monolithically integrated component, e.g., using various epitaxial processes, but it is also possible to produce the individual layers separately using suitable connection techniques and then stack them on top of each other.

The resulting semiconductor chip 2a has a bottom side or second main side 3b and a first main side or top side 3a. The bottom side 3b comprises a ball grid array arranged thereon with a plurality of contact elements 4d and 4c in the form of an array. This array allows a very dense concentration of individual contact elements on the bottom side of the semiconductor chip 2a. The underside 3b of the semiconductor chip 2a is also part of a rewiring layer 23. The rewiring layer 23 comprises several metallic lines 230 arranged within and at different depths, which are embedded in an insulating material and can also cross over or under each other. The lines 230 are connected to the contact surfaces 4d on the underside 3b of the rewiring layer on the one hand, and on the other hand lead to the top side of the rewiring layer, where they contact elements of a further metallic heat dissipation layer 22.

The rewiring layer 23 allows the various contacts for the ball grid array to be routed to different locations within the semiconductor chip in order to meet the design requirements of an active layer 20 with the integrated circuits 8 contained therein on the one hand, and to implement additional functionalities such as heat dissipation paths on the other. In addition, the redistribution layer 23 offers the opportunity to distribute the contacts of the ball grid array in a suitable manner over the surface 3b of the semiconductor chip.

A heat dissipation layer 22 is formed on the redistribution layer, which consists of or comprises a particularly heat-dissipating material. This allows heat generated during operation by the integrated circuits 8 in the active layer 20, as well as heat from the laser array 5, to be efficiently dissipated. In this embodiment, the heat dissipation layer is arranged between the redistribution layer and the active layer 20, but other design options are also possible here, both in the vertical position and in the lateral orientation for the heat dissipation layer.

The active layer 20 comprises several integrated circuits 8, which are connected to the contact elements 4d or 4c. In addition, the different integrated circuits 8 can be connected to each other in order to implement various analog and digital functionalities. For example, integrated circuits include driver circuits for the current and voltage supply of the laser arrangement according to the proposed principle, but also a control circuit, temperature compensation circuits, digital control, and correction circuits for current and voltage supply.

A further substrate layer 21 is applied to the active layer 20, which has various feedthroughs 9a and 9b. These vias can now be connected to corresponding contact areas 4a, 4b on the surface 2b and the integrated circuits 8 in the active layer, but they can also pass through or bypass areas of the active layer 20 with the circuits and, for example, contact the lines 230 on the rewiring layer 23. The through-plating 9a and 9b shown here in the substrate 21 lead to contact areas 4a and 4b on the first main side 3a of the semiconductor chip and the surface 3b of the substrate 21.

This allows further passive or active SMD components to be attached to the top side and the first main side 3a of the semiconductor chip in the area of the contact elements 4b, as shown in FIG. 1, for example. The SMD components have different sizes in the um or mm range and can be soldered to the contact elements 4b. For this purpose, a solder paste is applied to the contact surface 4b, onto which the SMD components are placed and then connected by heating. This allows components to be stacked, i.e., arranged one above the other, thus reducing the lateral space required. At the same time, the contact surfaces 4b on the top side of the substrate layer 21 can be connected to the wiring system 23 via feedthroughs in the substrate layer 21 through the active layer 20, the heat dissipation layer 22 into the wiring system 23, for example to create a direct connection between contacts 4d on the underside 3b of the semiconductor chip and contacts 4a or 4b on the top side. In other words, various combinations are conceivable here and are limited only by the complexity of the necessary rewiring and the size.

A hermetically sealed laser assembly 5 is now mounted on the top side 3a of the semiconductor chip. This comprises a laser diode 51, for example a VCSEL or an edge-emitting laser, which is mounted on a submount 52 for better heat dissipation. The submount 52 has an electrical through-hole connection, not shown here, and is mechanically and electrically connected to a contact surface 4a on the upper side 3a of the semiconductor chip 2a. At least one further contact surface 4a is electrically connected via a bond wire 53 to a contact on the upper side of the laser assembly 51. The combination of laser assembly 51 and submount 52 allows for suitable heat dissipation on the one hand and direct control via the corresponding contact elements 4a on the upper side on the other. However, direct arrangement on the contact surfaces is also possible. Similarly, the laser diode can be placed directly on the contact surface as a flip chip.

At the same time, the laser diode 51 can be applied to the surface with the submount 52 during production and aligned appropriately in a test mode. In this way, the laser diode is tested together with the semiconductor chip to ensure correct functionality.

A glass cap 50 is then placed with its lower edge along a connection surface 210 and mechanically connected to this connection surface on the upper side 3a of the semiconductor chip. This creates a hermetically sealed interior space 54 in which the contact elements 4a for controlling the laser diode and the laser itself are housed. During production, this space can also be filled with a protective gas so that no deposits settle on the laser facet during operation of the laser assembly in conventional manufacturing techniques. The glass cap 50 is transparent to the laser radiation itself and, depending on its design, may also have integrated optical components or sensors for detecting damage to the cap 50. The contact elements 4b are located outside the glass cap on the same side as the contact elements 4a, in particular in the immediate vicinity of the glass cap 50. This allows additional passive or active elements, e. g., capacitors, to be arranged as close as possible to the laser diode 51. By such approach, the impedance of the system is kept at a low level, enabling the realization of precise pulse shapes.

In some further aspects, the connection surface 210 on which the glass cap is placed is electrically connected to the integrated circuit, so that it serves as a sensor for possible damage and a break in the hermetic seal. Similarly, the glass cap itself may also have an electrical metallic conductor on the inside, the resistance or other electrical properties of which change in the event of damage.

In the present embodiment, it is also possible for the laser diode 51 to be designed as a vertical laser diode VCSEL or as an edge-emitting laser with a sideways emission characteristic. The joint arrangement of the laser on a surface of the semiconductor chip 2a with subsequent hermetic sealing creates a very compact component package that can be placed directly and immediately on another carrier, for example in the form of a PCB board. In particular, the laser arrangement with the semiconductor chip and the other components can also be tested and aligned directly, eliminating the need for subsequent alignment or testing.

FIG. 2 shows another example of the proposed principle. In this example, the semiconductor chip again has a bunch of contact areas 4b on its surface, on which another semiconductor chip 2b is placed in this case. Some of these contacts on the surface 3a of the semiconductor chip 2a are now connected directly to contacts 4c of the ball grid array on the underside 3b of the first semiconductor chip for power and voltage supply. In this embodiment, several semiconductor chips are thus stacked on top of each other and connected to each other mechanically and electrically, with feedthroughs and contacts being present at least on the first semiconductor chip 2a.

The semiconductor chip 2b offers additional functionality and is operatively connected to the semiconductor chip 2a and the integrated circuits 8 ( ). In this respect, the two semiconductor chips 2a and 2b not only perform different functions, but can also be manufactured using a suitable technology. For example, semiconductor chip 2a can implement analog circuit techniques for supplying current and voltage to laser array 5, whereby sufficient heat dissipation is also generated here due to the larger lateral dimensions of semiconductor chip 2a. For this reason, the semiconductor chip 2a with its larger lateral dimension also comprises one or more heat dissipation layers, one of which is shown here as layer 22. Integrated circuits 8, which generate a large amount of heat during operation of the semiconductor chip 2a, are spaced laterally from the laser assembly 5 so that different heat paths can be established in the heat dissipation layer 22. On the one hand, this is a path that extends from the laser assembly 5 towards the wiring layer 23, and on the other hand, a path that also leads from the integrated circuit 8 into the heat dissipation layer and into The semiconductor chip 2b comprises a digital control and monitoring system for the analog circuits 8 in the first semiconductor chip 2a. During operation, the digital control and monitoring system regularly generates significantly lower power dissipation, so that the heating of the chip 2b is kept within limits and no further measures need to be taken in this regard.

In the embodiment shown, a metal connecting surface 210 is also provided, which is located next to the contact surfaces 4a on the upper side 3a of the semiconductor chip 2a and surrounds these contact surfaces. The connection surface 210 is made of metal and serves as a support surface for the edges of the glass cap 50 after the glass cap 50 has been placed on the connection surface 210. As shown in this embodiment in FIG. 2, a laser beam can be irradiated from above through the transparent material of the glass cap. This is absorbed in the area of the connection surface 210, causing the material of the surface of the edge of the glass cap and also the connection surface to melt slightly and thus form a material bond with each other. The material bond leads to a hermetic seal of the laser assembly 5 within the space 54 of the glass cap.

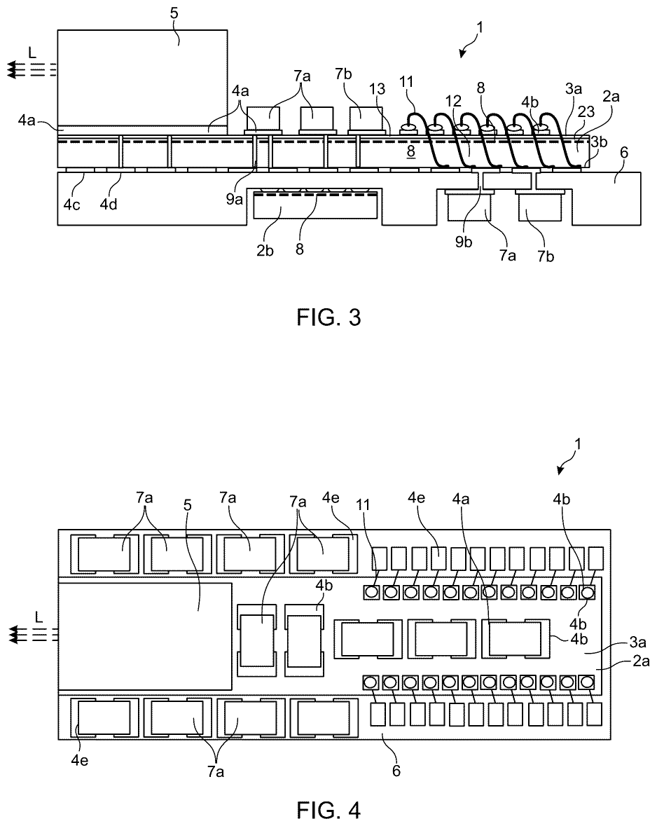

FIG. 3 shows a side view of another embodiment of an integrated component package 1 according to some aspects of the proposed principle. In particular, FIG. 3 shows an integrated component package 1 comprising first through-plugs 9a extending from the first main side 3a to the second main side 3b and electrically connecting contact surfaces of the first number of contact surfaces 4a to contact surfaces of the second number of contact surfaces 4b. A rewire layer 23 is arranged here below the surface 3a of the semiconductor chip, whereby the metallic lines in the rewire layer can also dissipate heat during operation of the laser arrangement. By means of the rewire layer 23, contact areas of the first number of contact areas 4a are provided over the entire first main upper side 3a. First through-plugs 9a can provide an electrical connection between contact areas of the second number of contact areas 4b and the rewiring layer 23, and the rewiring layer 23 can then lead these first through-plugs 9a, which extend vertically upward in particular, to other areas on the first main upper surface 3a.

In this embodiment, the semiconductor chip 2a is attached with its contact surfaces 4c and 4d on its underside 3b to a carrier 6, which is designed as a double-sided PCB board. As shown, metallic contacts are applied to the top side of the PCB board 6, to which the semiconductor chip 2a is soldered. Some of these contacts are routed through the PCB board to the other side by means of feed-throughs 9b, where they also contact contacts on which further components 7a, 7b, and 2b are mounted. These can be passive and active SMD components, but also semiconductor chips 2b with more complex integrated circuits. The components are housed in recesses so that the underside of the PCB board is essentially level. Alternatively, these components can also be mounted on a planar surface on contact areas there.

FIG. 4 shows another design in top view. Here, the component package with the semiconductor chip 2 is applied to a carrier 6 according to the proposed principle. Several SMD components 7a are placed on contact surfaces on the carrier 6 close to the semiconductor chip 2a. Similarly, SMD components 7a are placed on a plurality of surface contacts 4b on the surface of the semiconductor chip 2a. In addition, further bonding wires 11 are provided which, in addition to the first through-plated contacts 9a, provide an electrical connection between contact surfaces 4e on the carrier 6 and contact surfaces 4b on the first main side 3a of the first semiconductor chip 2a. Such bonding wires 11 allow the number of first through-plugs 9a required, for example, to provide sufficient contact areas on the first main side 3a of the first semiconductor chip 2a to be reduced. A metallic heat sink can be provided on the PCB board directly below the semiconductor chip, in particular in the area of the laser arrangement 5, so that effective heat dissipation is achieved via this and electrical contacting takes place via the bond wires.

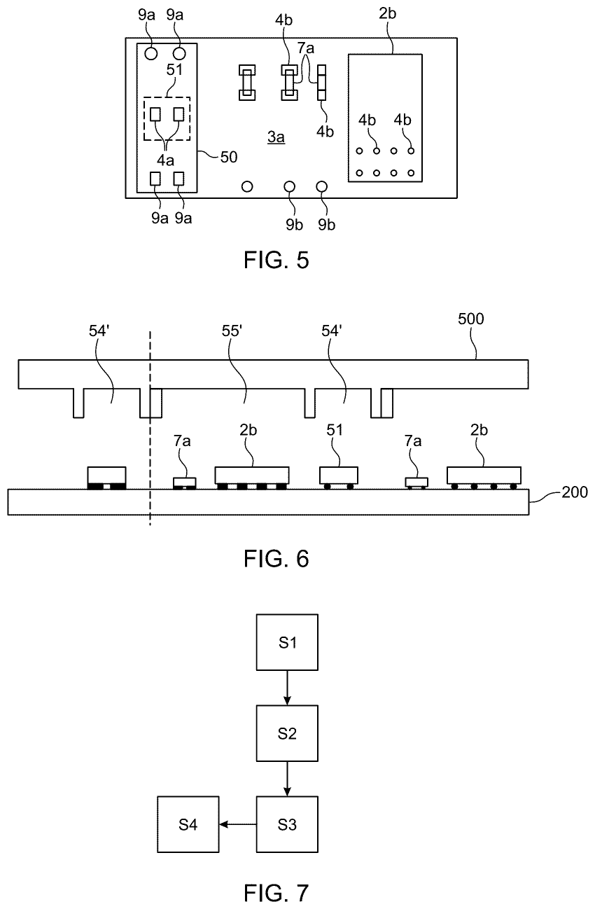

FIG. 5 shows another schematic design of a component package based on the proposed principle. In this design, the semiconductor chip 2a is essentially rectangular in shape, with several through-plated contacts 9a and contact surfaces 4a provided in a left-hand area within a hermetically sealed space for the implementation of a laser arrangement 51. A transparent glass cap 50 encloses the through-plated contacts 9a and the contact areas 4a and is hermetically connected to the surface of the semiconductor chip. The through-plated contacts 9a lead to the contact areas 4a on the surface of the semiconductor chip 2a for controlling the laser arrangement 51.

In this way, it is also possible to use the through-plated holes 9a as contact surfaces for SMD components. Additional contact surfaces 9b and 4b are located at various positions on the surface of the semiconductor chip 2a outside the area sealed with the glass cap. These are equipped with active or passive components 7a. Some contact areas can also remain free in this context if this is provided for in the design or if they are used for compensation and tuning in the further operation of the laser arrangement 5. A semiconductor chip 2b is electrically and mechanically connected to the surface with the contact areas 4b. The contact surfaces 4b on the surface 3a of the semiconductor chip 2a are designed to be soldered to a ball grid array of another semiconductor chip 2b. Accordingly, the semiconductor chip 2a can itself have a ball grid array for contacting as well as a number of contact surfaces designed to accommodate another semiconductor chip with a ball grid array.

The embodiments of a component package shown here can be manufactured as individual components, but also as a plurality of such components within a wafer assembly, and can be separated in a subsequent step after completion of the component package. FIG. 6 shows a representation during such a manufacturing process.

The semiconductor chips are manufactured in a wafer assembly 200, for example, using an epitaxial manufacturing process on a wafer. For this purpose, several layers of doped and structured semiconductor materials are applied to a semiconductor substrate, and the integrated circuits, the wiring layer, and other elements are formed in these layers. The processes used for this are tailored to the material system, the circuit design, and other parameters. In this example, the wafer assembly 200 is based on silicon, as this technology is well understood and also has the necessary properties for further processing, such as temperature resistance to withstand the temperatures required for soldering and attaching the glass cap.

The semiconductor chip can then either be connected to a separately produced substrate layer, for example by means of wafer-to-wafer bonding, or this layer is in turn deposited on the individual integrated circuits as an additional layer. The substrate layer not only serves to protect the integrated circuits, but can also be used for heat distribution or heat dissipation. The total thickness of the circuit is in the range of a few hundred micrometers to approximately 1 to 2 mm. The wafer composite can thus contain the various integrated circuits, with the design and arrangement corresponding to the subsequent structure of the semiconductor chip. In a further process step, the contact surfaces are then formed on the surface of the semiconductor chip or substrate layer in the form of metallic connection surfaces. In this example, these are equipped in a further step with active or passive SMD components as well as further integrated circuits.

In this context, FIG. 6 shows a structure in combination with a wafer 200 in which the various circuits are integrated to form a plurality of semiconductor chips. Several passive components 7a are applied to the individual contact surfaces and contact areas on the surface. Furthermore, individual second semiconductor chips 2b are now soldered onto the corresponding contact areas, so that the composite stacks several chips on top of each other. These process steps are carried out separately from a later assembly with an optoelectronic component 51, for example a laser arrangement.

This ensures that the optoelectronic component is not exposed to excessive thermal stress. Furthermore, after the semiconductor chips have been completely assembled and after the optoelectronic component has been attached and electrically secured, it can also be extensively tested, so that the overall test depth is increased and a combination of tests on the semiconductor chips and the optoelectronic component is directly possible. During or after testing, the component 51 is aligned, if necessary, so that a specific direction and radiation characteristic is defined for the component package.

At the same time, a glass carrier 500 is provided in which a large number of different cavities 54′ and 55′ are etched. The depth of the individual trenches and their size are selected so that when the glass carrier 500 is placed on the wafer assembly, it forms cavities above the optoelectronic component 51 and the various integrated circuits ( ) and SMD components. Accordingly, the individual cavities 54′ and 55′ are aligned so that the integrated circuits and the optoelectronic components can be accommodated therein.

In a further manufacturing step, the wafer composite 200 and the glass wafer 500 are aligned with each other and the glass wafer is placed on the carrier composite. Subsequently, optical measures, such as laser irradiation, can be used to melt the underside of the glass wafer's edge, thereby bonding it to the surface of the semiconductor substrate. Alternatively, or additionally, connection surfaces are provided on the surface of the wafer composite 200, which are covered with solder paste, for example. After the glass wafer has been placed on top, the solder on the connection surfaces is melted either by heat or by laser irradiation, thus bonding the glass wafer 500 to the wafer composite 200. The glass wafer can also be pressed down slightly during this process to improve the connection. The individual component packages can then be separated along the dotted line to produce the integrated component packages shown above.

FIG. 7 shows the individual manufacturing steps in a flow chart.

In step S1, a carrier, in particular a PCB board, is provided and a first semiconductor chip with a first main side and an opposite second main side is attached to it. A number of contact areas are formed on the first main side, which are intended for connection to a laser package. On the second main side, there is a second number of contact areas, which in turn are intended for connection to a carrier. The semiconductor chip also comprises at least one layer with an integrated circuit. In this context, a layer does not have to be two-dimensional.

Rather, this term is to be understood in the sense of the present application as meaning that one or more integrated circuits are formed within the semiconductor chip. These can extend both vertically and laterally. Such designs, as well as the associated restrictions due to design, physical limits, and the like, are known to those skilled in the art.

Parts of the first number of contact areas and parts of the second number of contact areas are connected to the integrated circuit(s), so that the integrated circuits are suitable for supplying the optoelectronic component and for controlling the optoelectronic component.

Subsequently, in step S2, an optoelectronic component is applied to the contact surfaces provided for this purpose on the semiconductor chip and electrically connected to it. In this context, the optoelectronic component can also be aligned or otherwise tested with the third semiconductor chip. Next, in step S3, a glass cap is placed on top, the circumferential edge of which now sits on the surface of the semiconductor chip and, in particular, on a connection surface provided for this purpose. In step S4, the underside of the edge of the glass cap is connected to the first main side of the semiconductor chip in a material-locking, in particular hermetic, manner.

This material bond can be achieved in various ways, for example by glass bonding the underside of the rim of the glass cap to the connection surface. It is also possible to provide welding or soldering in a suitable manner. In some aspects, it is conceivable that the connection surfaces are in a slight recess or are formed by such a recess into which the glass body is inserted. This also allows for improved alignment of the glass cap and precise positioning. After applying the glass cap, additional elements, such as SMD elements, can be applied by soldering outside the hermetic cavity and the glass cap. Various technologies are also available for this purpose, such as SAC reflow soldering or soldering with a suitable paste.

In this context, it is possible to reverse the order in which the glass cap or optoelectronic component and the individual SMD components or other integrated circuits are applied. This would have the advantage of reducing any thermal stress on the optoelectronic component. Mechanical aspects may also argue in favor of a hermetic package being larger, making some areas more difficult to reach for mounting SMD components. In addition, this makes it possible to test the combination of semiconductor chip and optoelectronic component before the glass cap is finally applied. In the event of possible damage or faults, the individual components can be easily separated from each other or faulty parts replaced. This simplifies the test procedure and reduces costs.

As already shown in FIG. 6 above, the integrated circuit can be formed in combination with, for example, a ball grid array, but also with conventional contact surfaces on the underside. The optoelectronic component can also be mounted on the contact surfaces by soldering, but also by appropriate silver sintering or other liquid material connections. For this purpose, the top side of the semiconductor chip is equipped with a corresponding structure, for example, gold metallization, whereby this metallization forms the connection surfaces and connects the integrated circuits with corresponding through-plating or contacts that extend into the substrate layer.

The optoelectronic component can be placed either on a submount or directly on the corresponding contact surfaces using flip chip technology. Alternatively, classic bonding is also possible, in which a bond wire is routed from a contact surface on the semiconductor chip to a corresponding contact surface on the optoelectronic component or laser diode. After final testing of the component package, the wafer assembly can be separated by sawing or laser cutting or other means, so that separate packages are available.

1. A component package, in particular laser package, comprising:
a semiconductor chip with a first main side and an opposite second main side,
wherein a first number of contact pads are formed on the first main side for connecting an optoelectronic component, in particular a laser assembly,
wherein a second number of contact pads are formed on the second main side for connection to a carrier, in particular a PCB;
wherein the semiconductor chip comprises at least one layer with an integrated circuit which is coupled to at least parts of the first number and at least parts of the second number of contact pads for its power supply;
an optoelectronic component connected to at least two of the first number of contact areas; and
a glass cap which is arranged above the optoelectronic component, forming a space, and is connected to the first main side in a substantially inorganic manner, in particular hermetically,
wherein the glass cap is arranged such that at least a portion of the first number of contact surfaces is located outside the glass cap.

2. The component package according to claim 1, wherein the connection of the glass cap to the first main side is essentially carbon-free.

3. The component package according to claim 1, further comprising a connection surface, in particular a metallic connection surface, which at least partially surrounds at least two of the first number of contact surfaces and is designed:
to be connected to the underside of an edge of the glass cap in a material-locking manner;
to be bonded to an underside of an edge of the glass cap, in particular by means of glass bonding;
to be welded to an underside of an edge of the glass cap, in particular by welding a surface of the underside;
to be soldered to an underside of an edge of the glass cap.

4. The component package according to claim 1, wherein the second number of contact surfaces are formed by a ball grid array, of which at least some are optionally electrically connected to each other with contact surfaces of the first number of contact surfaces by a conductor.

5. The component package according to claim 1, wherein the semiconductor chip has at least one rewiring layer connected to at least some of the first and second numbers of contact surfaces and formed above and/or below a layer with the integrated circuit.

6. The component package according to claim 5, wherein the rewiring layer has through-plugs which connect at least some of the first number of contact surfaces to at least some of the second number of contact surfaces and/or wherein the rewiring layer has through-plugs which move essentially along a circumferential edge.

7. The component package according to claim 1, wherein the semiconductor chip comprises a substrate layer made of a semiconductor material, in particular Si, which is free of an integrated circuit.

8. The component package according to claim 1, wherein at least two of the first number of contact areas are designed for connection to a passive SMD component,
wherein the at least two of the first number of contact areas are arranged outside the glass cap; and/or
wherein a plurality of the first number of contact areas are de-signed for connection to a second semiconductor chip with at least one integrated circuit, wherein the plurality of the first number of contact areas are arranged outside the glass cap.

9. The component package according to claim 1, wherein the first number of contact surfaces are at least partially integrated into the first main side; or wherein surfaces of the first number of contact areas at least partially protrude beyond a surface of the first main side.

10. The component package according to claim 1, wherein one or more integrated circuits are arranged at a lateral distance from at least two of the first number of contact surfaces, and wherein a first integrated circuit with a higher heat dissipation capacity in operation than a second integrated circuit has a greater lateral distance than the second integrated circuit.

11. The component package according to claim 1, wherein the connection surface forms part of a sensor designed to detect damage to the glass cap; or in which a sensor for detecting damage to the glass cap is further formed in the semiconductor chip or on the semiconductor chip.

12. A method for processing a component package, in particular a laser package, comprising:
providing a semiconductor chip with a first main side and an opposite second main side,
wherein a first number of contact areas are formed on the first main side for connecting an optoelectronic component, in particular a laser arrangement,
wherein a second number of contact pads are formed on the second main side for connection to a carrier, in particular a PCB;
wherein the semiconductor chip comprises at least one layer with an integrated circuit which is coupled to at least parts of the first number and at least parts of the second number of contact pads for its power supply;
applying an optoelectronic component to two of the first number of contact areas and connecting it to these;
placing a glass cap on the first main side to form a space above the optoelectronic component; and
substantially inorganic, material-bonded, in particular hermetic, bonding of a circumferential edge of the glass cap to the first main side of the semiconductor chip.

13. The method for processing a component package according to claim 12, in which the material-locking, in particular hermetic, connection comprises:
bonding, in particular glass bonding, of an underside of the edge of the glass cap to a connection surface, in particular a metallic connection surface, which surrounds at least two of the first number of contact surfaces;
welding an underside of an edge of the glass cap to a connection surface, in particular a metallic connection surface, which surrounds at least two of the first number of contact surfaces, in particular by welding a surface of the under-side; and
soldering an underside of an edge of the glass cap to a connection surface, in particular a metallic connection surface, which at least partially surrounds at least two of the first number of contact surfaces.

14. The method for processing a component package according to claim 12, further comprising at least one of the following steps:
applying the semiconductor chip with the second number of contact pads to a carrier, in particular a PCB;
applying a passive SMD component to two of the first number of contact areas, in particular outside the glass cap;
applying a passive SMD component to two of the first number of contact pads, in particular outside the glass cap;
applying a second semiconductor chip with at least one integrated circuit to two of the first number of contact areas, in particular outside the glass cap.

15. The method for processing a component package according to claim 12, in which the semiconductor chip has a substrate layer made of a semiconductor material, in particular Si, which is free of an integrated circuit.

16. The method for processing a component package according to claim 12, in which one or more integrated circuits are arranged at a lateral distance from at least two of the first number of contact surfaces, wherein a first integrated circuit with a higher heat dissipation during operation than a second integrated circuit has a greater lateral distance than the second integrated circuit.
